(19) United States
(12) Patent Application Publication
(10) Pub. No.: US 2025/0081774 A1
(43) Pub. Date: Mar. 6, 2025

(54) DISPLAY SUBSTRATE, DISPLAY DEVICE, AND DISPLAY SUBSTRATE MANUFACTURING METHOD

(71) Applicants: Chengdu BOE Optoelectronics Technology Co., Ltd., Chengdu, Sichuan (CN); BOE Technology Group Co., Ltd., Beijing (CN)

(72) Inventors: Chaojun ZENG, Beijing (CN); Baosheng HE, Beijing (CN); Xiaolong WANG, Beijing (CN); Minghui WANG, Beijing (CN); Quan LIU, Beijing (CN)

(21) Appl. No.: 18/693,966

(22) PCT Filed: Jul. 31, 2023
(86) PCT No.: PCT/CN2023/110307

§ 371 Date: Mar. 21, 2024

(30) Foreign Application Priority Data
Aug. 16, 2022 (CN) 202210980600.3

(51) Int. Cl. H10K 59/131

(52) U.S. Cl. CPC H10K 59/131

(57) ABSTRACT

The display substrate comprises a display area and a peripheral area surrounding the display area. The display substrate comprises: a substrate, a first and second conductive layers located on the substrate and sequentially arranged in the direction away from the substrate, and a first organic insulating layer located between the first and second conductive layers. The first conductive layer comprises a plurality of first metal wires extending in a first direction. The second conductive layer comprises a plurality of second metal wires extending in the first direction. In the peripheral area, the first organic insulating layer is divided, and the edge of the first organic insulating layer extends in a second direction and forms a first step. The second direction intersects with the first direction. The first step comprises at least one protruding structure and at least one recess structure located between the adjacent second metal wires.

### CROSS-REFERENCE TO RELATED APPLICATION

The present application is a U.S. National Phase Entry of International Application No. PCT/CN2023/110307 having an international filing date of Jul. 31, 2023, which claims priority from Chinese Patent Application No. 202210980600.3, filed to the CNIPA on Aug. 16, 2022. Contents of the above-identified application should be interpreted as being incorporated into the present application by reference.

### TECHNICAL FIELD

The present disclosure relates to the field of display technologies, and in particular to a display substrate, a display device and a manufacturing method of the display substrate.

### BACKGROUND

During the manufacturing of organic light-emitting diode (OLED) display substrate, it is necessary to adopt multiple organic insulation layers to flatten the structure therein. Due to the large thickness of the organic insulation layers and the need of bonding and bending in a peripheral region of the OLED display substrate, multiple organic insulation layers will be stacked at an edge of the OLED display substrate to form a thick step.

At the bottom of the step, underexposure is easy to occur, which leads to metal residue between adjacent metal traces when metal traces are formed on the organic insulation layers, which makes short circuit between adjacent metal traces and causes circuit structure damage, thus affecting the display effect of the OLED substrate.

### SUMMARY

The present disclosure aims at solving at least one of the technical problems existing in the prior art, and provides a display substrate, a display device and a manufacturing method of the display substrate.

In a first aspect, an embodiment of the present disclosure provides a display substrate having a display region and a peripheral region around the display region. The display substrate includes a base, a first conductive layer and a second conductive layer located on the base and arranged in sequence along a direction away from the base, and a first organic insulation layer located between the first conductive layer and the second conductive layer. The first conductive layer includes a plurality of first metal traces extending along a first direction, and the second conductive layer includes a plurality of second metal traces extending along the first direction.

In the peripheral region, the first organic insulation layer is disconnected, and an edge of the first organic insulation layer extends along a second direction and forms a first step. The second direction intersects with the first direction.

The first step includes at least one convex structure and at least one concave structure located between adjacent second metal traces.

In an example, the second metal traces and the first metal traces are electrically connected at the first step.

In an example, the display substrate further includes a third conductive layer located at a side of the second conductive layer facing away from the base, and a second organic insulation layer located between the second conductive layer and the third conductive layer. The third conductive layer includes a plurality of third metal traces extending along the first direction.

In the peripheral region, the second organic insulation layer is disconnected, and an edge of the second organic insulation layer extends along the second direction and forms a second step.

The second step includes at least one convex structure and at least one concave structure located between adjacent third metal traces.

In an example, the third metal traces and the second metal traces are electrically connected at the second step.

In an example, an orthographic projection of the second step on the base coincides with an orthographic projection of the first step on the base.

In an example, the display substrate further includes: a fourth conductive layer located between the first conductive layer and the base and insulated from the first conductive layer. The fourth conductive layer includes a plurality of fourth metal traces extending along the second direction.

In the peripheral region, the first organic insulation layer is disconnected, and an edge of the first organic insulation layer extends along the first direction and forms a third step.

The third step includes at least one convex structure and at least one concave structure located between adjacent fourth metal traces.

In an example, the first organic insulation layer forms a first water-oxygen barrier groove at the third step.

In an example, in the peripheral region, the second organic insulation layer is disconnected, and an edge of the second organic insulation layer extends along the first direction and forms a fourth step.

The fourth step includes at least one convex structure and at least one concave structure located between adjacent fourth metal traces.

In an example, the second organic insulation layer forms a second water-oxygen barrier groove at the fourth step.

In an example, an orthographic projection of the fourth step on the base coincides with an orthographic projection of the third step on the base.

In an example, the display substrate further includes a third organic insulation layer located at a side of the third conductive layer facing away from the base.

The third organic insulation layer covers the first step and the second step, and is disconnected at the first water-oxygen barrier groove and the second water-oxygen barrier groove.

In an example, a shape of the concave structure is at least one of semicircle, triangle and square.

In a second aspect, an embodiment of the present disclosure provides a display device. The display device includes the display substrate provided as described above.

In a third aspect, an embodiment of the present disclosure provides a manufacturing method of a display substrate having a display region and a peripheral region around the display region. The manufacturing method of the display substrate includes: forming a first conductive layer on a base, and forming a plurality of first metal traces extending along a first direction by a patterning process; forming a first organic insulation layer on the first conductive layer, and patterning the first organic insulation layer so that the first organic insulation layer is disconnected in the peripheral region, and an edge of the first organic insulation layer extends along a second direction and forms a first step, the first step including at least one convex structure and at least one concave structure; and forming a second conductive layer on the first organic insulation layer and forming a plurality of second metal traces extending along the first direction by a patterning process, so that at least one convex structure and at least one concave structure are provided between adjacent second metal traces.

In an example, after forming a second conductive layer on the first organic insulation layer, and forming a plurality of second metal traces extending along the first direction by a patterning process, the method further includes: forming a second organic insulation layer on the second conductive layer, and patterning the second organic insulation layer so that the second organic insulation layer is disconnected in the peripheral region, and an edge of the second organic insulation layer extends along the second direction and forms a second step, the second step including at least one convex structure and at least one concave structure; and forming a third conductive layer on the second organic insulation layer, and forming a plurality of third metal traces extending along the first direction by a patterning process, so that at least one convex structure and at least one concave structure are provided between adjacent third metal traces.

### BRIEF DESCRIPTION OF DRAWINGS

FIG. 1 is a schematic diagram of a structure of an exemplary display substrate.

FIG. 2 is a schematic diagram of a cross-sectional structure of the display substrate shown in FIG. 1 taken along an A-A′ direction.

FIG. 3 is a schematic diagram of a structure of a display substrate according to an embodiment of the present disclosure.

FIG. 4 is a schematic diagram of a cross-sectional structure of the display substrate shown in FIG. 3 taken along a B-B′ direction.

FIG. 5 is a schematic top view of a structure of the display substrate shown in FIG. 4.

FIG. 6 is a schematic diagram of a cross-sectional structure of the display substrate shown in FIG. 3 taken along a C-C′ direction.

FIG. 7 is a schematic top view of a structure of the display substrate shown in FIG. 6.

FIG. 8 is another schematic top view of a structure of the display substrate shown in FIG. 4.

FIG. 9 is yet another schematic top view of a structure of the display substrate shown in FIG. 4.

FIG. 10 is another schematic top view of a structure of the display substrate shown in FIG. 6.

FIG. 11 is yet another schematic top view of a structure of the display substrate shown in FIG. 6.

FIG. 12 is a schematic flowchart of a manufacturing method of a display substrate according to an embodiment of the present disclosure.

### DETAILED DESCRIPTION

To make those skilled in the art better understand technical solutions of the present disclosure, the present disclosure is described in further detail below with reference to the accompanying drawings and the detailed description.

Unless otherwise defined, technical terms or scientific terms used in the present disclosure should have the meanings as commonly understood by those having ordinary skills in the art to which the present disclosure pertains. The “first”, “second” and similar words used in the present disclosure do not indicate any order, quantity, or importance, but are used only for distinguishing different components. Similarly, similar words such as “a”, “an” or “the” do not in denote a limitation on quantity, but rather denote the presence of at least one. “Include”, “contain”, or similar words mean that elements or objects appearing before the words cover elements or objects listed after the words and their equivalents, but do not exclude other elements or objects. “Connection”, “coupling”, or a similar word is not limited to a physical or mechanical connection, but may include an electrical connection, whether direct or indirect. “Upper”, “lower”, “left”, “right” and the like are used for representing a relative positional relationship, and when an absolute position of a described object is changed, the relative positional relationship may also be correspondingly changed.

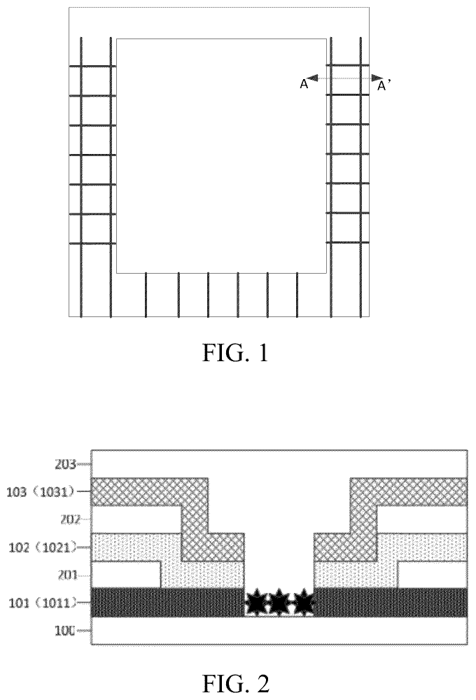

FIG. 1 is a schematic diagram of a structure of an exemplary display substrate. The display substrate has a display region and a peripheral region around the display region, as shown in FIG. 1. FIG. 2 is a schematic diagram of a cross-sectional structure of the display substrate shown in FIG. 1 taken along an A-A′ direction. As shown in FIG. 2, the display substrate includes a base 100, and a plurality of conductive layers located on the base 100, for example, a first conductive layer 101, a second conductive layer 102, and a third conductive layer 103. An organic insulation layer is provided between adjacent conductive layers. For example, a first organic insulation layer 201 is provided between the first conductive layer 101 and the second conductive layer 102, a second organic insulation layer 202 is provided between the second conductive layer 102 and the third conductive layer 103, and a third organic insulation layer 203 is provided on the third conductive layer 103.

The first conductive layer 101 may specifically include a plurality of first metal traces 1011 extending along a first direction, the second conductive layer 102 may specifically include a plurality of second metal traces 1021 extending along the first direction, and the third conductive layer 103 may specifically include a plurality of third metal traces 1031 extending along the first direction. The first organic insulation layer 201, the second organic insulation layer 202, and the third organic insulation layer 203 can not only prevent short circuit between adjacent conductive layers, but also flatten the surface of metal traces in the conductive layers covered by the first organic insulation layer 201, the second organic insulation layer 202, and the third organic insulation layer 203, so as to form a relatively flat surface and ensure attachment with other film layers.

A plurality of signal lines, such as a data line, a scan line, a power signal line, an initialization signal line, a reset signal line are also provided in the display substrate. In order to reduce the resistance of the signal lines in the display substrate, the signal lines are generally formed into a structure of a plurality of conductive layers. For example, the data line may be formed into a three-layer structure of the first metal traces 1011, the second metal traces 1021, and the third metal traces 1031. In the peripheral region, the first metal traces 1011, the second metal traces 1021 and the third metal traces 1031 may be electrically connected.

In order to increase flatness, the thickness of each organic insulation layer in the display substrate is generally made thicker. For example, the thickness of a single organic insulation layer can reach 1.5 microns to 3 microns, and the thickness of a three-layer organic insulation layer can reach nearly 10 microns. Thick organic insulation layer has a large drop height at the disconnected surface, which is easy to form a higher step. When forming a conductive layer on the organic insulation layer and patterning it to form a metal trace, the bottom of the step is easy to receive insufficient light during exposure, and photoresist residue often occurs, which leads to metal residue. The risk of short circuit easily occurs between adjacent metal traces across the disconnected surface.

In order to solve at least one of the above technical problems, embodiments of the present disclosure provide a display substrate, a display device and a manufacturing method of the display substrate. The display substrate, the display device and the manufacturing method of the display substrate provided by the embodiments of the present disclosure will be further described in detail with reference to the drawings and the detailed description.

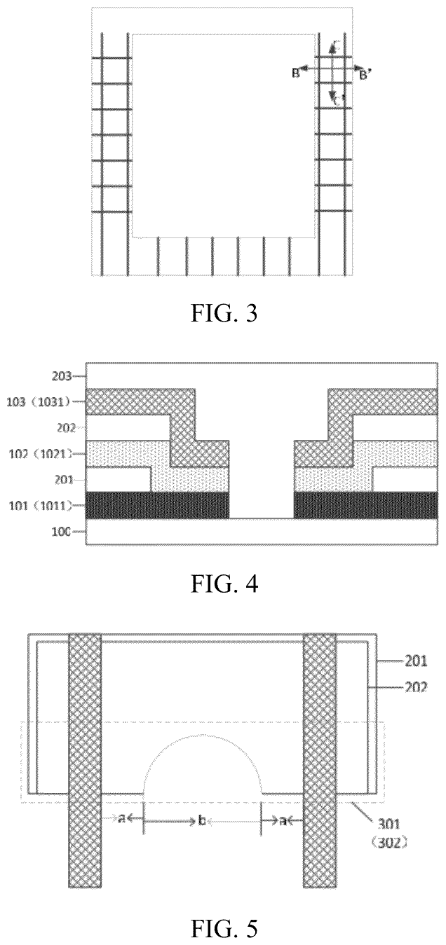

In a first aspect, an embodiment of the present disclosure provides a display substrate. FIG. 3 is a schematic diagram of a structure of a display substrate provided by an embodiment of the present disclosure. As shown in FIG. 3, the display substrate has a display region and a peripheral region around the display region. FIG. 4 is a schematic diagram of a cross-sectional structure of the display substrate shown in FIG. 3 taken along a B-B′ direction, and FIG. 5 is a schematic top view of a structure of the display substrate shown in FIG. 4. As shown in FIGS. 4 and 5, the display substrate includes a base 100, a first conductive layer 101 and a second conductive layer 102 located on the base 100 and arranged in sequence along a direction away from the base 100, and a first organic insulation layer 201 located between the first conductive layer 101 and the second conductive layer 102. The first conductive layer 101 includes a plurality of first metal traces 1011 extending along a first direction. The second conductive layer 102 includes a plurality of second metal traces 1021 extending along the first direction. In the peripheral region, the first organic insulation layer 201 is disconnected, and an edge of the first organic insulation layer 201 extends along a second direction and forms a first step 301. The second direction intersects with the first direction. The first step 301 includes at least one convex structure a and at least one concave structure b located between adjacent second metal traces 1021.

The base 100 may be made of a rigid material, such as glass, which can improve the load-bearing capacity of the base 100 to other film layers thereon. Alternatively, the base 100 may also be made of a flexible material, such as polyimide (PI), which can improve the bending resistance and tensile resistance of the whole display substrate, and prevent the base 100 from breaking due to stress generated in the bending, stretching and twisting processes, resulting in poor circuit opening. In a practical application, the material of the base 100 can be reasonably selected according to the actual needs, so as to ensure that the display substrate has good performance.

The first conductive layer 101 and the second conductive layer 102 may be made of the same conductive material, for example, one of the metal materials such as aluminum, titanium, copper, molybdenum. The first conductive layer 101 may include a plurality of first metal traces 1011 extending along the first direction. The second conductive layer 102 may include a plurality of second metal traces 1021 extending along the first direction. The first metal traces 1011 and the second metal traces 1021 may extend from the display region of the display substrate to the peripheral region. Specifically, the first metal traces 1011 and the second metal traces 1021 may form a film layer of a thin film transistor in the display region, and may also form a signal line for transmitting signals, such as a data line. In the display region, the first metal traces 1011 and the second metal traces 1021 are insulated by the first insulation layer 201, and in the peripheral region, the first metal traces 1011 and the second metal traces 1021 are lapped with each other to transmit the same data signal.

In the peripheral region, since the first organic insulation layer 201 is provided in a part of the region and the first organic insulation layer 201 is not provided in a part of the region, the first organic insulation layer 201 is disconnected, and an edge of the first organic insulation layer 201 extends along the second direction and forms a first step 301. The second direction intersects with the first direction, that is, an extension direction of the first step 301 intersects with an extension direction of the first metal traces 1011 (or the second metal traces 1021).

The first step 301 includes at least one convex structure a and at least one concave structure b between adjacent second metal traces 1021. The convex structure a and the concave structure b can make a side surface of the first step 301 change from an original flat straight disconnected surface to an uneven curved disconnected surface.

In the display substrate provided by the embodiment of the present disclosure, the plurality of first metal traces 1011 and the plurality of second metal traces 1021 each extend along the same direction from the display region to the peripheral region, and a thick first organic insulation layer 201 is provided between the first metal traces 1011 and the second metal traces 1021. In the peripheral region, the first organic insulation layer 201 is disconnected. At the disconnected position, the edge of the first organic insulation layer 201 extends along the second direction and forms the first step 301, and the side surface of the first step 301 has a convex structure a and a concave structure b. At least one convex structure a and at least one concave structure b are provided between adjacent second metal traces 1021. During the lithography process, the illuminated area of the photoresist coated at the convex structure a is greatly increased and can be completely removed. Even if the photoresist coated at the concave structure b is partially residual, no continuous residual metal is formed at the whole bottom of the first step 301, thereby avoiding short circuit between the adjacent first metal traces 1011 and the adjacent second metal traces 1021, and further improving the display effect of the display substrate.

In some embodiments, the second metal traces 1021 and the first metal traces 1011 are electrically connected at the first step 301.

The second metal traces 1021 and the first metal traces 1011 are electrically connected at the first step 301 to form a signal line with a double layer structure, such as a data line with a double layer structure. The double layer structure can increase the thickness of the signal line, thereby reducing the resistance of the signal line, improving the signal transmission efficiency, and further improving the display effect of the display substrate.

In some embodiments, as shown in FIGS. 4 and 5, the display substrate further includes a third conductive layer 103 located at a side of the second conductive layer 102 facing away from the base 100, and a second organic insulation layer 202 located between the second conductive layer 102 and the third conductive layer 103. The third conductive layer 103 includes a plurality of third metal traces 1031 extending along the first direction. In the peripheral region, the second organic insulation layer 202 is disconnected, and an edge of the second organic insulation layer 202 extends along the second direction and forms a second step 302. The second step 302 includes at least one convex structure a and at least one concave structure b between adjacent third metal traces 1031.

The third conductive layer 103 may be made of the same conductive material as the first conductive layer 101 and the second conductive layer 102, for example, one of the metal materials such as aluminum, titanium, copper, molybdenum. The third conductive layer 103 may include a plurality of third metal traces 1031 extending along the first direction. Likewise, the third metal traces 1031 may extend from the display region of the display substrate to the peripheral region. Specifically, the third metal traces 1031 may also form a film layer of a thin film transistor in the display region, or may form a signal line for transmitting signals, such as a data line. In the display region, the third metal traces 1031 and the second metal traces 1021 are insulated by the second insulation layer 202, and in the peripheral region, the third metal traces 1031 and the second metal traces 1021 are lapped with each other to transmit the same data signal.

In the peripheral region, the second organic insulation layer 202 is disconnected, and an edge of the second organic insulation layer 202 extends along the second direction at the disconnected position and forms the second step 302. A side surface of the second step 302 has a convex structure a and a concave structure b, and one convex structure a and one concave structure b are at least provided between adjacent third metal traces 1031. During the lithography process, the illuminated area of the photoresist coated at the convex structure a is greatly increased and can be completely removed. Even if the photoresist coated at the concave structure b is partially residual, no continuous residual metal is formed at the whole bottom of the second step 302, thereby avoiding short circuit between the adjacent third metal traces 1031, and further improving the display effect of the display substrate.

In some embodiments, the third metal traces 1031 and the second metal traces 1021 are electrically connected at the second step 302.

The third metal traces 1031 and the second metal traces 1021 are electrically connected at the second step 302 to form a signal line with a double layer structure or even a three layer structure, such as a data line with a double layer structure or a three layer structure. The thickness of the signal line can be increased, thereby reducing the resistance of the signal line, improving the signal transmission efficiency, and further improving the display effect of the display substrate.

In some embodiments, an orthographic projection of the second step 302 on the base 100 coincides with an orthographic projection of the first step 301 on the base 100.

The first step 301 and the second step 302 have the same shape, and the same mask plate can be used in the manufacturing process, so that the number of masks can be reduced and the manufacturing cost can be saved. At the same time, the first step 301 and the second step 302 are completely overlapped, so that the lap stability among the first metal traces 1011, the second metal traces 1021 and the third metal traces 1031 can be ensured, and the contact resistance can be prevented from being increased due to the instable lap.

It should be noted here that the first conductive layer 101, the second conductive layer 102, and the third conductive layer 103 may all be source-drain conductive layers in the display substrate. For example, the first conductive layer 101 may be specifically a first source-drain conductive layer, which may form source-drain electrodes of a thin film transistor in the display region, and may also form a signal line such as a data line. The second conductive layer 102 may be specifically a second source-drain conductive layer, and the third conductive layer 103 may be specifically a third source-drain conductive layer, which may form a switching electrode between a drain electrode of a thin film transistor in the display region and an anode of a light emitting device, and may also form a signal line, such as a data line. It can be understood that, in the display substrate, the corresponding resistance reduction effect can be achieved by generally configuring the source-drain conductive layer in the display substrate as three layers. Alternatively, the source-drain conductive layer in the display substrate can be configured as two layers or other numbers. For example, only the first conductive layer 101 (the first source-drain conductive layer) and the second conductive layer 102 (the second source-drain conductive layer) are provided in the display substrate.

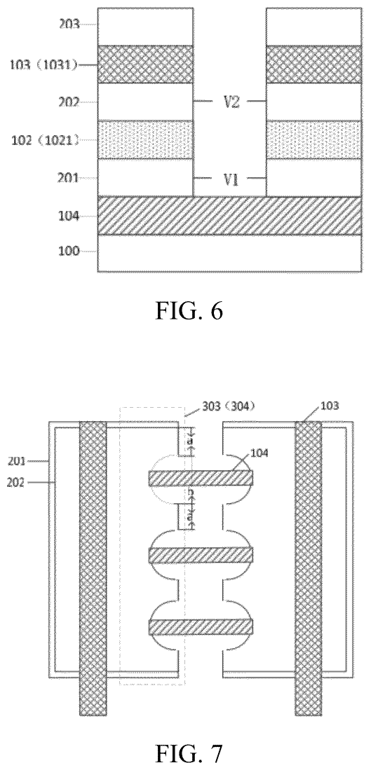

FIG. 6 is a schematic diagram of a cross-sectional structure of the display substrate shown in FIG. 3 taken along a C-C′ direction, and FIG. 7 is a schematic top view of a structure of the display substrate shown in FIG. 6. As shown in FIGS. 6 and 7, the display substrate further includes a fourth conductive layer 104 located between the first conductive layer 101 and the base 100 and insulated from the first conductive layer 101. The fourth conductive layer 104 includes a plurality of fourth metal traces 1041 extending along the second direction. In the peripheral region, the first organic insulation layer 201 is disconnected, and an edge of the first organic insulation layer 201 extends along the first direction and forms a third step 303. The third step 303 includes at least one convex structure a and at least one concave structure b located between adjacent fourth metal traces 1041.

The fourth conductive layer 104 may be specifically a gate conductive layer which may be made of one or more of metal materials, such as gold, silver, aluminum, titanium, copper, molybdenum. An inorganic insulation layer may be provided between the fourth conductive layer 104 and the first conductive layer 101 such that the insulation layer and inorganic layer between the fourth conductive layer 104 and the first conductive layer 101 may be made of one or more of silicon nitride, silicon oxide and silicon oxynitride. The fourth conductive layer 104 may include a plurality of fourth metal traces 1041 extending along the second direction and the fourth metal traces 1041 may extend from the display region to the peripheral region of the display substrate. Specifically, the fourth metal traces 1041 may be scan lines and may transmit a gate scan signal.

In the peripheral region, the first insulation layer 201 may be disconnected. At the disconnected position, the edge of the first organic insulation layer 201 extends along the first direction and forms the third step 303, and the side surface of the third step 303 has a convex structure a and a concave structure b. One convex structure a and concave structure b may at least be provided between adjacent fourth metal traces 1041. During the lithography process, the illuminated area of the photoresist coated at the convex structure a is greatly increased and can be completely removed. Even if the photoresist coated at the concave structure b is partially residual, no continuous residual metal, which is the metal of the second conductive layer 102, is formed at the whole bottom of the third step 303, thereby avoiding short circuit between the adjacent fourth metal traces 1041, and further improving the display effect of the display substrate.

In some embodiments, the first organic insulation layer 101 forms a first water-oxygen barrier groove V1 at the third step 303.

The first water-oxygen barrier groove V1 can disconnect the first organic insulation layer 201 to prevent water and oxygen and the like from being immersed into the display region from the peripheral region of the display substrate and to prevent the water and oxygen and the like from damaging the light emitting device in the display region. It should be explained that, since the inorganic insulation layer has a small thickness and does not conduct water and oxygen and the like, the inorganic insulation layer may not be disconnected so that the first conductive layer 101 does not have residual due to the step structure during the manufacturing process. Therefore, the structures of the first conductive layer 101 and the inorganic insulation layer are not shown in both FIGS. 6 and 7.

In some embodiments, in the peripheral region, the second organic insulation layer 202 is disconnected and an edge of the second organic insulation layer 202 extends along the first direction and forms a fourth step 304. The fourth step 304 includes at least one convex structure a and at least one concave structure b between adjacent fourth metal traces 1041.

In the peripheral region, the second insulation layer 202 may be disconnected. At the disconnected position, the edge of the second organic insulation layer 202 extends along the first direction and forms the fourth step 304, and the side surface of the fourth step 304 has a convex structure a and a concave structure b. One convex structure a and concave structure b may at least be provided between adjacent fourth metal traces 1041. During the lithography process, the illuminated area of the photoresist coated at the convex structure a is greatly increased and can be completely removed. Even if the photoresist coated at the concave structure b is partially residual, no continuous residual metal, which is the metal of the third conductive layer 103, is formed at the whole bottom of the third step 303, thereby avoiding short circuit between the adjacent fourth metal traces 1041, and further improving the display effect of the display substrate.

In some embodiments, the second organic insulation layer 202 forms a second water-oxygen barrier groove V2 at the fourth step 304.

The second water-oxygen barrier groove V2 can disconnect the second organic insulation layer 202 to prevent water and oxygen and the like from being immersed into the display region from the peripheral region of the display substrate and to prevent the water and oxygen and the like from damaging the light emitting device in the display region. In a practical application, the fourth step 304 and the third step 303 need to be completely overlapped. On the one hand, the number of masks can be reduced and the manufacturing cost can be saved. On the other hand, the overlapping of the fourth step 304 and the third step 303 can make the formed first water-oxygen barrier groove V1 and the second water-oxygen barrier groove V2 completely overlapped, ensuring that the first organic insulation layer 201 and the second insulation layer 202 are disconnected at the same position and avoiding water-oxygen invasion.

In some embodiments, the display substrate further includes a third organic insulation layer 203 located at a side of the third conductive layer 103 facing away from the base 100. The third organic insulation layer 203 covers the first step 301 and the second step 302 and is disconnected at the first water-oxygen barrier groove V1 and the second water-oxygen barrier groove V2.

The third organic insulation layer 203 can further flatten the first step 301 and the second step 302 to ensure attachment with other film layers. The third organic insulation layer 203 can be disconnected at the same position as the first organic insulation layer 201 and the second organic insulation layer 202 to avoid water-oxygen invasion.

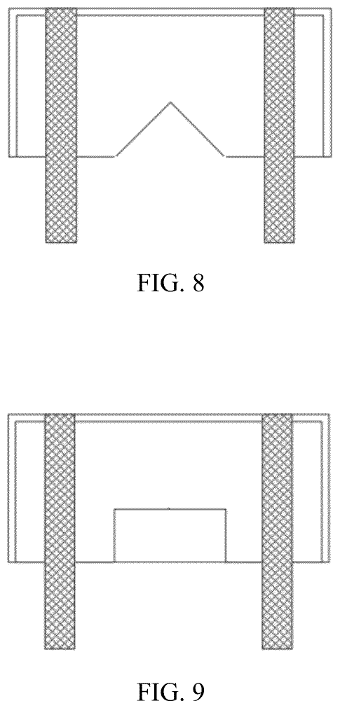

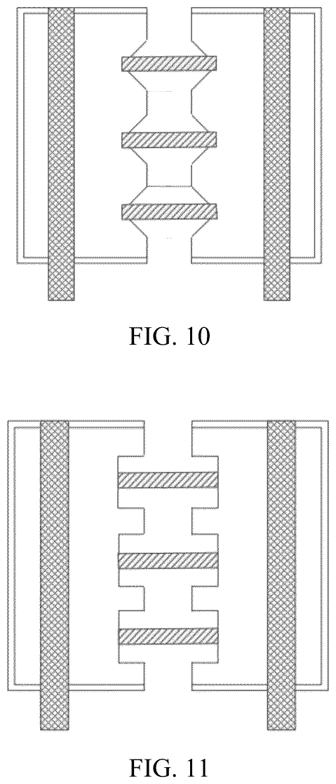

In some embodiments, FIG. 8 is another schematic top view of a structure of the display substrate shown in FIG. 4, FIG. 9 is yet another schematic top view of a structure of the display substrate shown in FIG. 4, FIG. 10 is another schematic top view of a structure of the display substrate shown in FIG. 6, and FIG. 11 is yet another schematic top view of a structure of the display substrate shown in FIG. 6. As shown in FIGS. 8 to 11, the shape of the concave structure b is at least one of semicircle, triangle and square.

The shape of the concave structure b can be at least one of semicircle, triangle and square, so that the side surface of the step structure formed at the edge of the organic insulation layer can be changed from the original flat straight disconnected surface into an uneven curved disconnected surface, and the continuous residual metal can be avoided when the conductive layer is formed on the organic insulation layer. Thus the risk of short circuit easily occurring between adjacent metal traces across the disconnected surface can be prevented, thereby improving the display effect of the display substrate.

In a second aspect, an embodiment of the present disclosure provides a display device including the display substrate provided in any of the above embodiments. The display device may be any product or component having a display function such as a mobile phone, a tablet computer, a television, a display, a notebook computer, a digital photo frame, a navigator. The embodiments of the present disclosure are not limited thereto. The implementation principle and technical effect of the display device are the same as the implementation principle and technical effect of the display substrate provided in any of the above embodiments, which will not be repeated here.

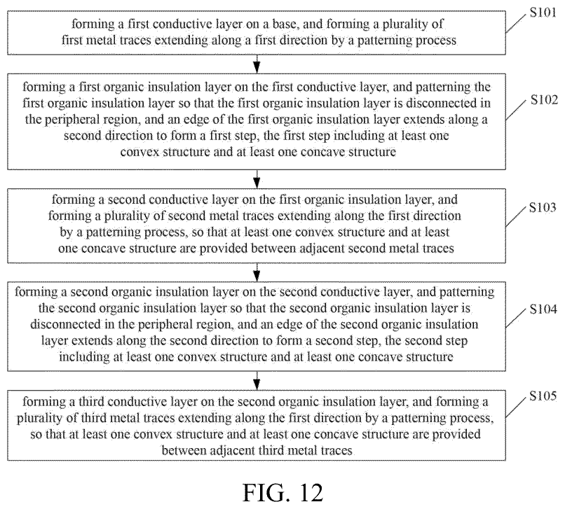

In a third aspect, an embodiment of the present disclosure provides a manufacturing method of a display substrate. FIG. 12 is a flowchart of a manufacturing method of a display substrate provided by an embodiment of the present disclosure. As shown in FIG. 12, the manufacturing method of the display substrate includes the following acts S101 to S103.
S101: forming a first conductive layer on a base, and forming a plurality of first metal traces extending along a first direction by a patterning process.
S102: forming a first organic insulation layer on the first conductive layer, and patterning the first organic insulation layer so that the first organic insulation layer is disconnected in the peripheral region, and an edge of the first organic insulation layer extends along a second direction and forms a first step, the first step including at least one convex structure and at least one concave structure.
S103: forming a second conductive layer on the first organic insulation layer, and forming a plurality of second metal traces extending along the first direction by a patterning process, so that at least one convex structure and at least one concave structure are provided between adjacent second metal traces.

In the manufacturing method of the display substrate provided by the embodiment of the present disclosure, the plurality of first metal traces and the plurality of second metal traces formed extend along the same direction from the display region to the peripheral region, and a thick first organic insulation layer is provided between the plurality of first metal traces and the plurality of second metal traces. In the peripheral region, the first organic insulation layer is disconnected. At the disconnected position, the edge of the first organic insulation layer extends along the second direction and forms the first step, and the side surface of the first step has a convex structure and a concave structure. At least one convex structure and at least one concave structure are provided between adjacent second metal traces. During the lithography process, the illuminated area of the photoresist coated at the convex structure is greatly increased and can be completely removed. Even if the photoresist coated at the concave structure is partially residual, no continuous residual metal is formed at the whole bottom of the first step, thereby avoiding short circuit between the adjacent first metal traces and the adjacent second metal traces, and further improving the display effect of the display substrate.

In some embodiments, as shown in FIG. 13, the manufacturing method of the display substrate further includes the following acts S104 and S105.
S104: forming a second organic insulation layer on a second conductive layer, and patterning the second organic insulation layer so that the second organic insulation layer is disconnected in the peripheral region, and an edge of the second organic insulation layer extends along the second direction and forms a second step, the second step including at least one convex structure and at least one concave structure.
S105: forming a third conductive layer on the second organic insulation layer, and forming a plurality of third metal traces extending along the first direction by a patterning process, so that at least one convex structure and at least one concave structure are provided between adjacent third metal traces.

In the peripheral region, the formed second organic insulation layer is disconnected. At the disconnected position, the edge of the second organic insulation layer extends along the second direction and forms the second step, and the side surface of the first step has a convex structure and a concave structure. At least one convex structure and at least one concave structure are provided between adjacent third metal traces. During the lithography process, the illuminated area of the photoresist coated at the convex structure is greatly increased and can be completely removed. Even if the photoresist coated at the concave structure is partially residual, no continuous residual metal is formed at the whole bottom of the second step, thereby avoiding short circuit between the adjacent third metal traces, and further improving the display effect of the display substrate.

It is to be understood that the above embodiments are only exemplary embodiments employed for the purpose of illustrating the principles of the present disclosure, however the present disclosure is not limited thereto. To those of ordinary skills in the art, various modifications and improvements may be made without departing from the essence and substance of the present disclosure, and these modifications and improvements are also considered to be within the scope of the present disclosure.

1. A display substrate having a display region and a peripheral region around the display region, wherein the display substrate comprises a base, a first conductive layer and a second conductive layer located on the base and arranged in sequence along a direction away from the base, and a first organic insulation layer located between the first conductive layer and the second conductive layer; the first conductive layer comprises a plurality of first metal traces extending along a first direction, the second conductive layer comprises a plurality of second metal traces extending along the first direction;
in the peripheral region, the first organic insulation layer is disconnected, and an edge of the first organic insulation layer extends along a second direction and forms a first step; the second direction intersects with the first direction.
the first step comprises at least one convex structure and at least one concave structure located between adjacent second metal traces.

2. The display substrate according to claim 1, wherein the second metal traces and the first metal traces are electrically connected at the first step.

3. The display substrate according to claim 2, wherein the display substrate further comprises a third conductive layer located at a side of the second conductive layer facing away from the base, and a second organic insulation layer located between the second conductive layer and the third conductive layer; the third conductive layer comprises a plurality of third metal traces extending along the first direction;
in the peripheral region, the second organic insulation layer is disconnected, and an edge of the second organic insulation layer extends along the second direction and forms a second step;
the second step comprises at least one convex structure and at least one concave structure located between adjacent third metal traces.

4. The display substrate according to claim 3, wherein the third metal traces and the second metal traces are electrically connected at the second step.

5. The display substrate according to claim 4, wherein an orthographic projection of the second step on the base coincides with an orthographic projection of the first step on the base.

6. The display substrate according to claim 3, wherein the display substrate further comprises a fourth conductive layer located between the first conductive layer and the base and insulated from the first conductive layer; the fourth conductive layer comprises a plurality of fourth metal traces extending along the second direction;
in the peripheral region, the first organic insulation layer is disconnected, and an edge of the first organic insulation layer extends along the first direction and forms a third step;
the third step comprises at least one convex structure and at least one concave structure located between adjacent fourth metal traces.

7. The display substrate according to claim 6, wherein the first organic insulation layer forms a first water-oxygen barrier groove at the third step.

8. The display substrate according to claim 7, wherein in the peripheral region, the second organic insulation layer is disconnected, and an edge of the second organic insulation layer extends along the first direction and forms a fourth step;
the fourth step comprises at least one convex structure and at least one concave structure located between adjacent fourth metal traces.

9. The display substrate according to claim 8, wherein the second organic insulation layer forms a second water-oxygen barrier groove at the fourth step.

10. The display substrate according to claim 9, wherein an orthographic projection of the fourth step on the base coincides with an orthographic projection of the third step on the base.

11. The display substrate according to claim 10, wherein the display substrate further comprises a third organic insulation layer located at a side of the third conductive layer facing away from the base;
the third organic insulation layer covers the first step and the second step, and is disconnected at the first water-oxygen barrier groove and the second water-oxygen barrier groove.

12. The display substrate according to claim 1, wherein a shape of the concave structure is at least one of semicircle, triangle, and square.

13. A display device, wherein the display device comprises the display substrate according to claim 1.

14. A manufacturing method of a display substrate having a display region and a peripheral region around the display region, wherein the manufacturing method of the display substrate comprises:
forming a first conductive layer on a base, and forming a plurality of first metal traces extending along a first direction by a patterning process;
forming a first organic insulation layer on the first conductive layer, and patterning the first organic insulation layer so that the first organic insulation layer is disconnected in the peripheral region, and an edge of the first organic insulation layer extends along a second direction and forms a first step; wherein, the first step comprises at least one convex structure and at least one concave structure; and
forming a second conductive layer on the first organic insulation layer and forming a plurality of second metal traces extending along the first direction by a patterning process, so that at least one convex structure and at least one concave structure are provided between adjacent second metal traces.

15. The manufacturing method of a display substrate according to claim 14, wherein after forming a second conductive layer on the first organic insulation layer and forming a plurality of second metal traces extending along the first direction by a patterning process, further comprising:
forming a second organic insulation layer on the second conductive layer and patterning the second organic insulation layer so that the second organic insulation layer is disconnected in the peripheral region, and an edge of the second organic insulation layer extends along the second direction and forms a second step; wherein, the second step comprises at least one convex structure and at least one concave structure; and
forming a third conductive layer on the second organic insulation layer and forming a plurality of third metal traces extending along the first direction by a patterning process, so that at least one convex structure and at least one concave structure are provided between adjacent third metal traces.

16. The display substrate according to claim 3, wherein a shape of the concave structure is at least one of semicircle, triangle, and square.

17. The display substrate according to claim 6, wherein a shape of the concave structure is at least one of semicircle, triangle, and square.

18. The display substrate according to claim 8, wherein a shape of the concave structure is at least one of semicircle, triangle, and square.

19. A display device, wherein the display device comprises the display substrate according to claim 2.

20. A display device, wherein the display device comprises the display substrate according to claim 3.
